(19) United States
(12) Patent Application Publication
(10) Pub. No.: US 2013/0248795 A1
(43) Pub. Date: Sep. 26, 2013

(54) NONVOLATILE MEMORY DEVICE AND METHOD FOR MANUFACTURING THE SAME

(71) Applicants: Kensuke Takahashi, Kanagawa-ken (JP); Kotaro Fujii, Nagasaki-ken (JP)

(72) Inventors: Kensuke Takahashi, Kanagawa-ken (JP); Kotaro Fujii, Nagasaki-ken (JP)

(21) Appl. No.: 13/600,359

(22) Filed: Aug. 31, 2012

(30) Foreign Application Priority Data
Mar. 21, 2012 (JP) 2012-064570

(51) Int. Cl. H01L 45/00

(52) U.S. Cl. 257/1; 438/382; 257/E45.002

(57) ABSTRACT

According to one embodiment, a nonvolatile memory device includes a first function layer. The first function layer includes a first electrode layer, a second electrode layer, and a variable resistance layer. The second electrode layer is opposed to the first electrode layer. The variable resistance layer is provided between the first electrode layer and the second electrode layer. Resistance state of the variable resistance layer is variable. The first function layer includes a first intermediate layer. The first intermediate layer is provided between the first electrode layer and the variable resistance layer. The first intermediate layer contacts the first electrode layer and the variable resistance layer.

### CROSS-REFERENCE TO RELATED APPLICATIONS

This application is based upon and claims the benefit of priority from the prior Japanese Patent Application No. 2012-064570, filed on Mar. 21, 2012; the entire contents of which are incorporated herein by reference.

### FIELD

Embodiments described herein relate generally to a nonvolatile memory device and a method for manufacturing the same.

### BACKGROUND

As a nonvolatile memory device utilizing a resistance change, there has been known a conductive bridging RAM (CBRAM) which changes a value of resistance by making a metal positive ion precipitate so as to form a bridge formation (a conducting bridge) between electrodes, and ionizing the precipitated metal so as to break the bridge formation. In the CBRAM, a change of a value of resistance between the electrodes is stored as an information.

The CBRAM is provided with a first electrode layer (an ion source), a second electrode layer (a counter electrode), and a variable resistance layer (an ion diffusion layer) which is provided between the first electrode layer and the second electrode layer. In an element configuration mentioned above, if an electric voltage is applied between the first electrode layer and the second electrode layer, a metal ion is conducted from the first electrode layer, a conduction path is formed in the variable resistance layer, and a low resistance state is formed. On the other hand, if an electric voltage in a reverse direction is applied, the metal ion formed in the variable resistance layer is reversely conducted, and a high resistance state is formed.

In the nonvolatile memory device as mentioned above, it is important in manufacturing and property to achieve equalization of a film thickness of the first electrode layer and improvement of a close contact property between the first electrode layer and the variable resistance layer.

### BRIEF DESCRIPTION OF THE DRAWINGS

FIG. 1 is a schematic cross sectional view illustrating a configuration of a first function layer of a nonvolatile memory device according to a first embodiment;

FIG. 2 is a schematic cross sectional view illustrating a configuration of another first function layer;

FIG. 3 is a schematic cross sectional view illustrating a configuration of a second function layer of the nonvolatile memory device according to the first embodiment;

FIG. 4 is a schematic cross sectional view illustrating a configuration of anther second function layer;

FIGS. 5A to 5C are schematic cross sectional views illustrating a state of the function layer;

FIGS. 6A and 6B are schematic perspective views illustrating the cross point configuration of the nonvolatile memory device;

FIGS. 7A to 7F are schematic views illustrating an applied example of the memory cell;

FIGS. 8A to 9B are schematic cross sectional views illustrating a manufacturing method of a nonvolatile memory device according to reference examples;

FIGS. 10A to 11B are schematic cross sectional views illustrating a manufacturing method of a nonvolatile memory device according to the embodiment;

FIGS. 12A to 13B are schematic cross sectional views illustrating a manufacturing method of a nonvolatile memory device in accordance with another configuration; and

FIG. 14 is a schematic cross sectional view of a nonvolatile memory device having two stages of function layers.

### DETAILED DESCRIPTION

In general, according to one embodiment, a nonvolatile memory device includes a first function layer. The first function layer includes a first electrode layer, a second electrode layer, and a variable resistance layer. The second electrode layer is opposed to the first electrode layer. The variable resistance layer is provided between the first electrode layer and the second electrode layer. Resistance state of the variable resistance layer is variable. The first function layer includes a first intermediate layer. The first intermediate layer is provided between the first electrode layer and the variable resistance layer. The first intermediate layer contacts the first electrode layer and the variable resistance layer.

Various embodiments will be described hereinafter with reference to the accompanying drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

A nonvolatile memory device according to the embodiment is provided with a first function layer which includes a first electrode layer, a second electrode layer, and a variable resistance layer.

The second electrode layer is opposed to the first electrode layer.

The variable resistance layer is provided between the first electrode layer and the second electrode layer, and a resistance state is variable.

The first function layer includes a first intermediate layer which is provided between the first electrode layer and the variable resistance layer so as to come into contact with each of the first electrode layer and the variable resistance layer.

### First Embodiment

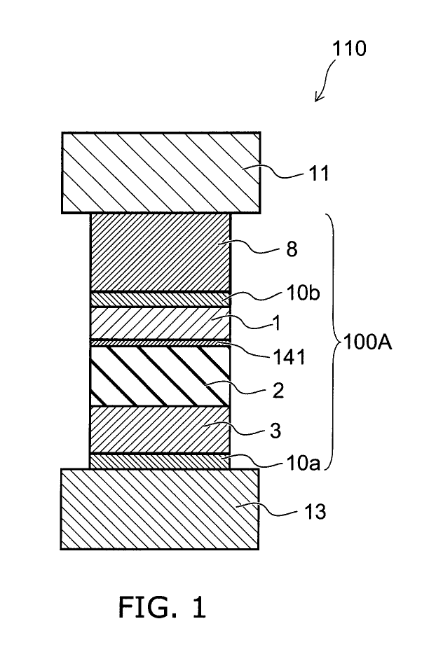

FIG. 1 is a schematic cross sectional view illustrating a configuration of a first function layer of a nonvolatile memory device according to a first embodiment.

As shown in FIG. 1, a nonvolatile memory device 110 according to the first embodiment is provided with a first function layer 100A including an ion source electrode 1 which is a first electrode layer, a counter electrode 3 which is a second electrode layer, and an ion diffusion layer 2 which is a variable resistance layer.

The counter electrode 3 is arranged so as to be opposed to the ion source electrode 1. The ion diffusion layer 2 is provided between the ion source electrode 1 and the counter electrode 3. The ion diffusion layer 2 has a function that a state of an electric resistance is changed by a filament of a metal atomic element (for example, a metal ion) which diffuses into the ion diffusion layer 2 from the ion source electrode 1. In other words, the first function layer 100A is a memory cell of the CBRAM.

The first function layer 100A includes a close contact layer 141 (a first intermediate layer) which is provided between the ion source electrode 1 and the ion diffusion layer 2. The close contact layer 141 is provided in such a manner as to come into contact with each of the ion source electrode 1 and the ion diffusion layer 2. On the basis of a provision of the close contact layer 141, a uniformity of a film thickness of the ion source electrode 1 is improved at a time of forming the ion source electrode 1 on the ion diffusion layer 2.

Next, a description will be given of a concrete example of the first function layer 100A.

As shown in FIG. 1, the first function layer 100A is provided between a word line 13 which is a first interconnect layer or a second interconnect layer, and a bit line 11 which is the second interconnect layer or the first interconnect layer. The first function layer 100A is laminated with a barrier metal 10a, the counter electrode 3, the ion diffusion layer 2, the close contact layer 141, the ion source electrode 1, a barrier metal 10b and a contact metal 8 in this order from the word line 13 toward the bit line 11.

A material of the ion source electrode 1 is at least one which is selected from the group consisted of a copper (Cu), a silver (Ag), an aluminum (Al), a cobalt (Co) and a nickel (Ni), and is preferably an element which does not react to a silicone. As the material of the ion source electrode 1, the Ag is most appropriate. A film thickness of the ion source electrode 1 is preferably set to be not less than 1 nanometer (nm) in the light of a secured uniformity of the film thickness, and be not more than 10 nm in the light of a process of a memory cell (for example, a reactive ion etching (RIE) process).

The ion diffusion layer 2 is not particularly constrained as long as the metal of the ion source electrode 1 can be ionized so as to be diffused, however, it is desirable that the better part thereof is in a non-crystalline state. For the ion diffusion layer 2, for example, there is employed at least one which is selected from the group consisted of a non-crystalline silicone film, a silicone oxide film, a silicone nitride film, and a transition metal oxide. The ion diffusion layer 2 may be configured such that at least two which are selected from the group are laminated. As the ion diffusion layer 2, there is preferably an amorphous silicone in which an impurity generating a conductive carrier is not added to the silicone, and there is further preferably an amorphous silicone in which a small amount of an oxygen or a nitrogen is added. The amorphous silicone includes a material in which a main component is an amorphous silicone.

It is preferable to set a concentration of the nitrogen (N) or the oxygen (O) included in the amorphous silicone to be not less than 2×10²⁰ cm⁻³ in the light of a suppression of an excessive diffusion of the metal ion forming the filament and be not less than 2×10²² cm⁻³ in the light of a secured heat resistance of a process. Further, in the light of a secured close contact property between the counter electrode 3 and the ion source electrode 1, it is preferable to set in a range which is not more than 1×10²³ cm⁻³.

The film thickness of the ion diffusion layer 2 is set in a range which is not less than 2 nm and not more than 20 nm. The film thickness of the ion diffusion layer 2 is set to be not more than 15 nm, preferably not more than 5 nm, in the light of a reduction of a set voltage. On the other hand, it is preferable that the film thickness of the ion diffusion layer 2 be set to be not less than 3 nm in the light of a reduction of a reverse current.

It is preferable that the concentration of the oxygen included in the ion diffusion layer 2 be set to the value as an average value, and it is not necessary to be uniformly distributed over each of the layers. For example, it may be configured such that the oxygen concentration in the vicinity of an interface between the ion diffusion layer 2 and ion source electrode 1 is lowest while the oxygen concentration in the vicinity of an interface between the ion diffusion layer 2 and the counter electrode 3 is highest, and the oxygen concentration in the amorphous silicone between both the interfaces changes in stages.

The counter electrode 3 is not particularly limited as long as it has a conductive property, and can secure a close contact property with the ion diffusion layer 2, and a stability of the process. The counter electrode 3 is preferably constructed by an n-type semiconductor, and most appropriately constructed by a silicone. As long as it can create an electron as a carrier, an element of the impurity which is added to the semiconductor is not limited, however, it is preferable that a concentration of the impurity be set to a range which is not less than 1×10¹⁸ cm⁻³ and not more than 1×10²⁰ cm⁻³ in a state in which all the elements are activated.

The material of the close contact layer 141 is a metal material in which an energy state of the ion source electrode 1 in the interface between the ion source electrode 1 and the close contact layer 141 becomes low, in the case of coming into contact with the metal of the ion source electrode 1. Specifically, a metal material in which a work function is smaller than the metal of the ion source electrode 1 is selected.

If the ion source electrode 1 and a metal different from the electrode 1 come into contact with each other, an electric double layer having an electric potential difference of a difference of work functions is formed in an interface of the both to bring the work functions into line with each other. In the case that the work function of the ion source electrode is smaller than the work function of the metal which comes into contact with the ion source electrode, a movement of an electric charge from the ion source electrode 1 to another metal is caused. As a result, an energy state in the vicinity of the contact interface of the pinned ion source electrode 1 becomes higher than an energy state in a whole balanced state. Accordingly, the metal material of the ion source electrode 1 tends to reduce a contact area with another metal so as to be agglutinated to lower the energy in the vicinity of the interface.

On the other hand, in the case that the work function of the ion source electrode 1 is larger than the work function of the metal coming into contact with it, a movement of the electric charge from the contact metal to the ion source electrode 1 is caused. As a result, the energy state in the vicinity of the contact interface of the ion source electrode 1 becomes lower in contradiction to the case mentioned above, and the agglutination is suppressed.

In the case that Ag is selected for the ion source electrode 1, at least one which is selected from the group consisted of a titanium (Ti), a niobium (Nb), a hafnium (Hf), the Al and a tantalum (Ta) is used as the metal which is used as the close contact layer 141, since the work function of the Ag is 4.31 eV. The work functions of these elements are respectively 4.14 eV, 4.01 eV, 3.9 eV, 4.13 eV and 4.19 eV.

A further preferable metal element for the ion source electrode 1 is Ti or Ta. Ti or Ta has a high affinity in a semiconductor process, and forms a stable silicide in the case of coming into contact with an amorphous silicone which is one example of the ion diffusion layer 2. Accordingly, no leak current is increased by a diffusion of the metal element forming the close contact layer 141 into the ion diffusion layer 2, or no switch property on the basis of an original ion source material is obstructed by making the close contact layer 141 itself the ion source. It is preferable that the film thickness of the close contact layer 141 be set to a range which is not less than 1 nm and not more than 3 nm in the light of the secured uniformity of the film thickness.

The barrier metal 10a is provided between the word line 13 and the counter electrode 3, and the barrier metal 10b is provided between the ion source electrode 1 and the contact metal 8. The barrier metals 10a and 10b are selected from one metal which is selected from the group consisted of a ruthenium (Ru), Ti, Ta, a tungsten (W), Hf and Al, or an oxide of the metal which is selected from this group, or a nitrogen of the selected metal. TiN is preferable for the barrier metal 10a in the light of the resistance value mentioned above, a set action of a memory cell, and a process resistance. Further, the film thickness of the barrier metal 10a is preferably in a range which is not less than 5 nm and not more than 15 nm.

In the nonvolatile memory device 110 provided with the first function layer 100A as mentioned above, since the close contact layer 141 is provided between the ion source electrode 1 and the ion diffusion layer 2, the agglutination is suppressed at a time of forming the ion source electrode 1 on the ion diffusion layer 2, and the uniform ion source electrode 1 is formed. Accordingly, it is possible to suppress a dispersion of the electric property in the memory cell, and a generation of a defect bit.

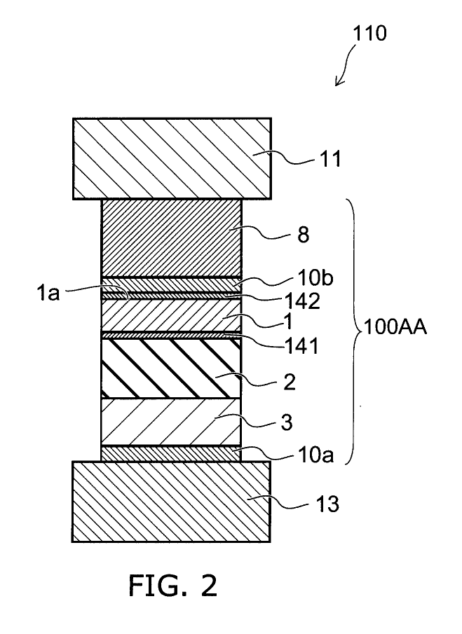

FIG. 2 is a schematic cross sectional view illustrating a configuration of another first function layer.

As shown in FIG. 2, as a configuration of another first function layer 100AA, there is provided a close contact layer (a second intermediate layer) 142 which comes into contact with a surface is of an opposite side to the close contact layer 141 of the ion source electrode 1. The close contact layer 142 is provided between the ion source electrode 1 and the barrier metal 10b.

In the nonvolatile memory device 110 which is provided with another first function layer 100AA, an improvement of the close contact force between the ion source electrode 1 and the barrier metal 10b can be achieved by the close contact layer 142, in addition to the effect in the case that the close contact layer 141 described above is provided.

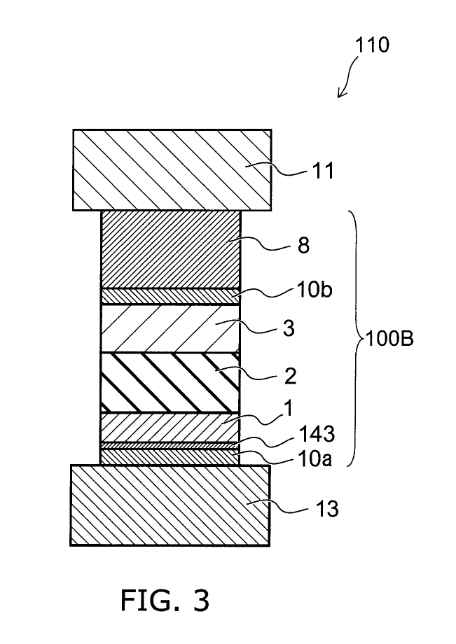

FIG. 3 is a schematic cross sectional view illustrating a configuration of a second function layer of the nonvolatile memory device according to the first embodiment.

As shown in FIG. 3, in the second function layer 100B, a laminating order of the ion source electrode 1, the ion diffusion layer 2 and the counter electrode 3 of the first function layer 100A shown in FIG. 1 is reversed.

In other words, the second function layer 100B is laminated with the barrier metal 10a, a close contact layer (a third intermediate layer) 143, the ion source electrode 1, the ion diffusion layer 2, the counter electrode 3, the barrier metal 10b and the contact metal 8 in this order from the word line 13 toward the bit line 11.

The material and the film thickness of each of the layers and each of the electrodes are the same as those the first function layer 100A which is described previously.

In the nonvolatile memory device 110 which is provided with the second function layer 100B mentioned above, since the close contact layer 143 is provided between the barrier metal 10a and the ion source electrode 1, an agglutination is suppressed at a time of forming the ion source electrode 1 on the barrier metal 10a, and a uniform ion source electrode 1 is formed. Accordingly, a dispersion of an electric property of the memory cell and a generation of a defect bit are suppressed.

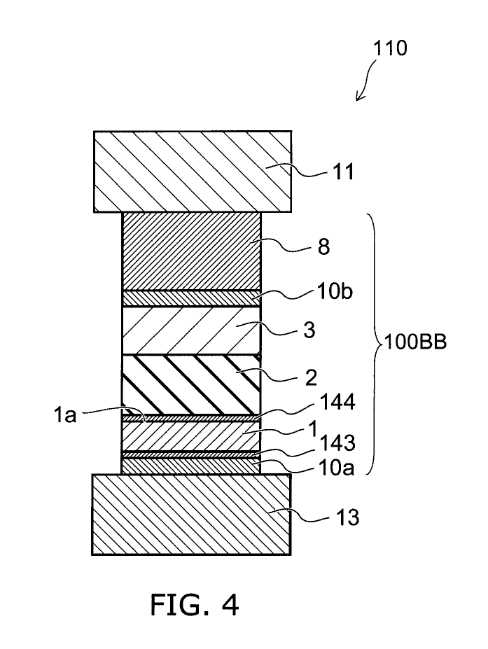

FIG. 4 is a schematic cross sectional view illustrating a configuration of anther second function layer.

As shown in FIG. 4, as a configuration of another second function layer 100BB, there is provided a close contact layer (a fourth intermediate layer) 144 which comes into contact with a surface is of an opposite side to the close contact layer 143 of the ion source electrode 1. In other words, the close contact layer 144 is provided between the ion source electrode 1 and the ion diffusion layer 2.

In the nonvolatile memory device 110 which is provided with the another second function layer 100BB, an improvement of a close contact force between the ion source electrode 1 and the ion diffusion layer 2 is achieved by the close contact layer 144, in addition to the effect in the case that the close contact layer 143 described above is provided.

Next, a description will be given of an action of the memory cell.

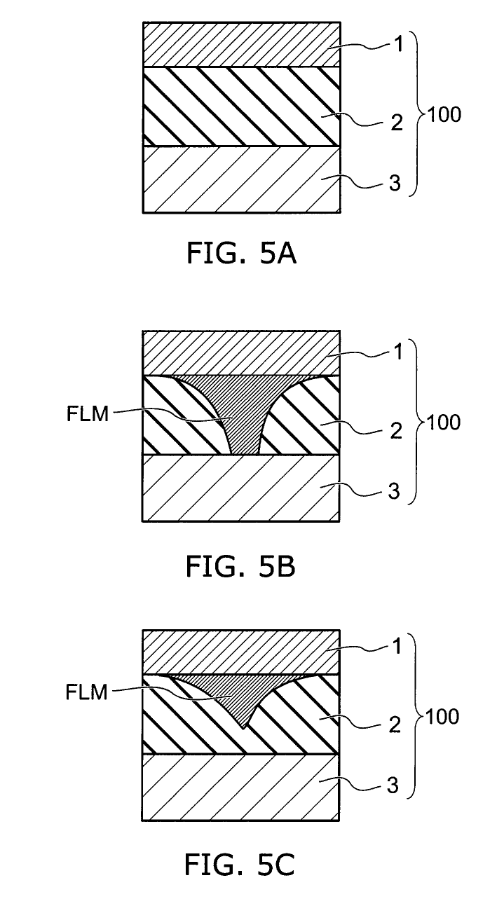

FIGS. 5A to 5C are schematic cross sectional views illustrating a state of the function layer.

In this case, a cross section of an outline configuration of a two terminal type switching element is shown in FIGS. 5A to 5C, and an illustration of the close contact layers 141, 142, 143 and 144 is omitted. Further, in the following description, the first function layers 100A and 100AA, and the second function layers 100B and 100BB are collectively called as the function layer 100.

In the element configuration shown in FIG. 5A, an electric voltage in a forward direction is applied between the ion source electrode 1 and the counter electrode 3 which become two terminals, a metal atomic element (a metal ion) is conducted to the ion diffusion layer 2 from the ion source electrode 1. Accordingly, a filament FLM as shown in FIG. 5B is formed within the ion diffusion layer 2. The filament FLM serves as a conduction path, putting the ion diffusion layer 2 into a low resistance (an on state).

On the other hand, a comparatively high voltage in a reverse direction is applied between the ion source electrode 1 and the counter electrode 3, the metal ion is reversely ion conducted and the conduction path by the filament FLM is disconnected, as shown in FIG. 5C. The ion diffusion layer 2 then comes into a high resistance state (an off state). On the basis of the transition of the resistance state of the ion diffusion layer 2 mentioned above, the function layer 100 serves as the switching element.

On the other hand, even in a state in which a comparatively low voltage is applied in a reverse direction under a low resistance state, the metal ion is weakly conducted in a direction of the ion source electrode 1 and a high resistance state is generated. Further, if the electric voltage is again applied in the forward direction, the conduction path is formed, and it comes back to the low resistance state (the on state). In other words, a rectifying property can be obtained with respect to a reverse direction bias.

Further, if a semiconductor is applied to the counter electrode 3, the counter electrode 3 is depleted in a state in which the electric voltage is applied in the reverse direction, whereby the conduction carrier does not exist in a contact point portion between the conduction path and counter electrode 3, so that the electric current hardly flows, and a strong rectifying property can be obtained with respect to the reverse direction bias.

In the light of the depletion of the counter electrode 3 mentioned above, it is preferable that a concentration of the impurity of the semiconductor material of the counter electrode 3 be low. It is preferable that the concentration of the impurity of the lower semiconductor electrode be low, in the light of the depletion.

As mentioned above, in the nonvolatile memory device 110 which is the CBRAM, since it is a voltage acting type element which controls the conduction path within the ion diffusion layer 2 by an electric field, an acting current is small in principle, and the conduction path is disconnected physically, a data retaining property is high.

Next, a description will be given of a cross point configuration of the nonvolatile memory device 110.

In general, in a memory device having a cross point type array, a reverse bias voltage which is the same as a selected cell is applied to an unselected cell which is opposed to the selected cell. Accordingly, in order to prevent an erroneous set or an erroneous reset of the unselected cell, it is necessary to construct the cell by laminating a rectifying element (diode) and a resistance change material. However, since the rectifying property is included in the cell itself in the CBRAM as mentioned above, it is not necessary to provide the rectifying element (diode). The configuration of the cell then becomes simple.

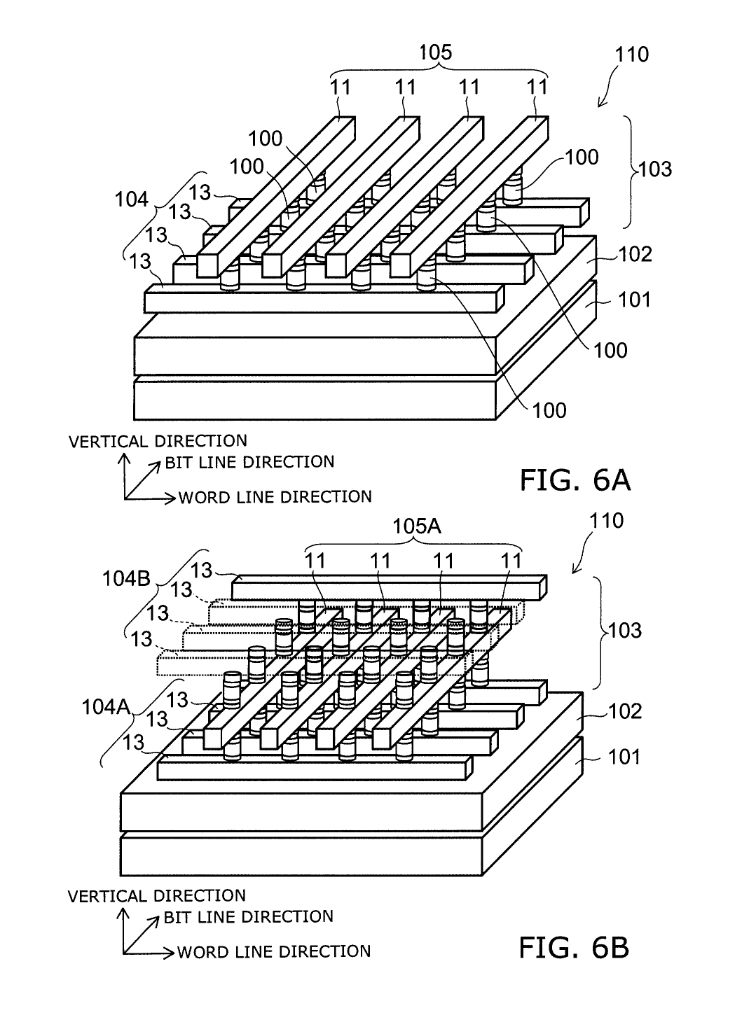

FIGS. 6A and 6B are schematic perspective views illustrating the cross point configuration of the nonvolatile memory device.

As shown in FIG. 6A, in the nonvolatile memory device 110 according to the embodiment, a silicone substrate 101 is provided. A drive circuit (not illustrated) of the nonvolatile memory device 110 is formed in an upper layer portion of the silicone substrate 101. An interlayer insulating film 102, for example, made of a silicone oxide is provided on the silicone substrate 101 in such a manner as to embed the drive circuit. A memory cell portion 103 of the cross point configuration is provided on the interlayer insulating film 102. The memory cell portion 103 is configured such as to be provided with a plurality of word lines 13, a plurality of bit lines 11, and a plurality of function layers 100 which are provided in the cross point of them.

In the memory cell portion 103, there are laminated a word line interconnect layer 104 including a plurality of word lines 13 which extend in one direction (hereinafter, refer to as “word line direction”) which is in parallel to an upper surface of the silicone substrate 101, and a bit line interconnect layer 105 including a plurality of bit lines 11 which extend in a direction (hereinafter, refer to as “bit line direction”) which intersects, for example, is orthogonal to the word line direction, in the direction which is in parallel to the upper surface of the silicone substrate 101, via an insulating layer (not illustrated).

The word line 13 and the bit line 11 are formed, for example, by W. Further, the word lines 13 are not in contact with each other, the bit lines 11 are not in contact with each other, and the word line 13 and the bit line 11 are not in contact with each other.

Further, in the closest point between each of the word lines 13 and each of the bit lines 11, there is provided the function layer 100 which extends in a direction (hereinafter, refer to as “vertical direction”) with respect to the upper surface of the silicone substrate 101. The function layer 100 is formed as a pillar shape between the word line 13 and the bit line 11. One memory cell is constructed by one function layer 100. Since the memory cell is arranged per the closest point between the word line 13 and the bit line 11, the nonvolatile memory device 110 becomes the cross point configuration.

FIG. 6A shows the memory cell portion 103 having one layer, however, the memory cell portion 103 may be configured such as to have multiple layers.

FIG. 6B shows the other cross point configuration. In the configuration shown in FIG. 6B, an electrode (a bit line 11 in FIG. 6B) provided between the upper and lower function layers 100 is shared.

In other words, as shown in FIG. 6B, a drive circuit (not illustrated) of the nonvolatile memory device 110 is formed in an upper layer portion of the silicone substrate 101, and the interlayer insulating film 102, for example, made of a silicone oxide is provided on the silicone substrate 101 in such a manner as to embed the drive circuit.

The memory cell portion 103 of the cross point configuration is provided on the interlayer insulating film 102. The memory cell portion 103 is provided with a first word line interconnect layer 104A which includes a plurality of word lines 13, a first bit line interconnect layer 105A which includes a plurality of bit lines 11, and a plurality of function layers 100 which are provided in the cross points the layers 104A and 105A. Further, the memory cell portion 103 is provided with a second word line interconnect layer 104B which includes a plurality of word lines 13, and a plurality of function layers 100 which are provided in the cross points between the second word line interconnect layer 104B and the first bit line interconnect layer 105A.

In the configuration example shown in FIG. 6B, in the upper and lower function layers 100, the first bit line interconnect layer 105A provided between them is shared.

In this case, in FIG. 6B, there is shown the example in which the function layer 100 having two layers is provided, however, further more function layers 100 may be laminated in the vertical direction. In this case, the upper and lower word lines 13 and the bit line 11 are alternately laminated, and the function layers 100 are arranged respectively in the cross points between the upper and lower word line 13 and the bit line 11.

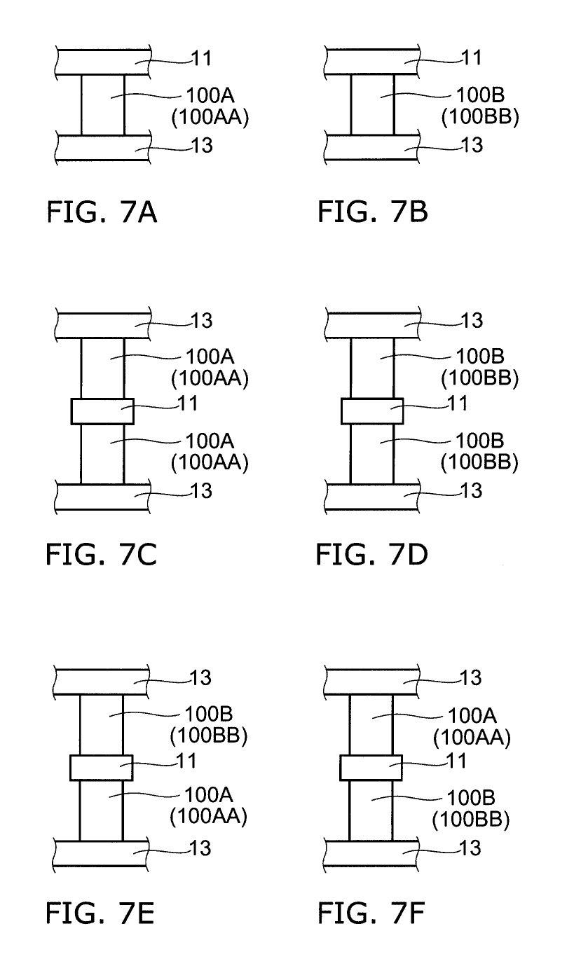

FIGS. 7A to 7F are schematic views illustrating an applied example of the memory cell.

In FIGS. 7A to 7F, there is shown the applied example of the function layer which is arranged in the cross points between the upper and lower word lines 13 and the bit line 11.

FIG. 7A is an example in which the first function layer 100A or 100AA is applied between the upper and lower word lines 13 and the bit line 11. It may be constructed as multiple stages by setting one layer of word line 13, one layer of bit line 11 and one layer of first function layer 100A (100AA) shown in FIG. 7A as one stage.

FIG. 7B is an example in which the second function layer 100B or 100BB is applied between the upper and lower word lines 13 and the bit line 1-1. It may be constructed as multiple stages by setting one layer of word line 13, one layer of bit line 11 and one layer of second function layer 100B (100BB) shown in FIG. 7B as one stage.

FIG. 7C is an example in which the word line 13, the bit line 11 and the word line 13 are alternately arranged vertically, and the first function layer 100A or 100AA is applied between them. In FIG. 7C, the example in which two layers of first function layers 100A (100AA) are laminated is shown, however, further more word lines 13 and bit lines 11 may be alternately laminated, and the first function layer 100A (100AA) may be applied between them.

FIG. 7D is an example in which the word line 13, the bit line 11 and the word line 13 are alternately arranged vertically, and the second function layer 100B or 100BB is applied between them. In FIG. 7D, the example in which two layers of second function layers 100B (100BB) are laminated is shown, however, further more word lines 13 and bit lines 11 may be alternately laminated, and the second function layer 100B (100BB) may be applied between them.

FIG. 7E is an example in which the word line 13, the bit line 11 and the word line 13 are alternately arranged vertically, the first function layer 100A or 100AA is applied onto the word line 13, and the second function layer 100B or 100BB is applied onto the bit line 11. FIG. 7E shows the example in which one layer of first function layer 100A (100AA) and one layer of second function layer 100B (100BB) are alternately laminated, however, further more word lines 13 and bit lines 11 may be alternately laminated, and the first function layer 100A (100AA) and the second function layer 100B (100BB) may be applied between them.

FIG. 7F is an example in which the word line 13, the bit line 11 and the word line 13 are alternately arranged vertically, the second function layer 100B or 100BB is applied onto the word line 13, and the first function layer 100A or 100AA is applied onto the bit line 11. FIG. 7F shows the example in which one layer of first function layer 100A (100AA) and one layer of second function layer 100B (100BB) are alternately laminated, however, further more word lines 13 and bit lines 11 may be alternately laminated, and the first function layer 100A (100AA) and the second function layer 100B (100BB) may be applied between them.

In this case, the nonvolatile memory device 110 according to the embodiment is not limited to the cross point configuration mentioned above. For example, the nonvolatile memory device 110 may be provided with the word line 13, and the bit line 11 which is separated from the word line 13 and is provided in parallel or nonparallel to the word line 13. In this configuration, the word line 13 is electrically conducted with the ion source electrode 1 or the counter electrode 3, and the bit line 11 is electrically conducted with the counter electrode 3 or the ion source electrode 1.

### Reference Examples

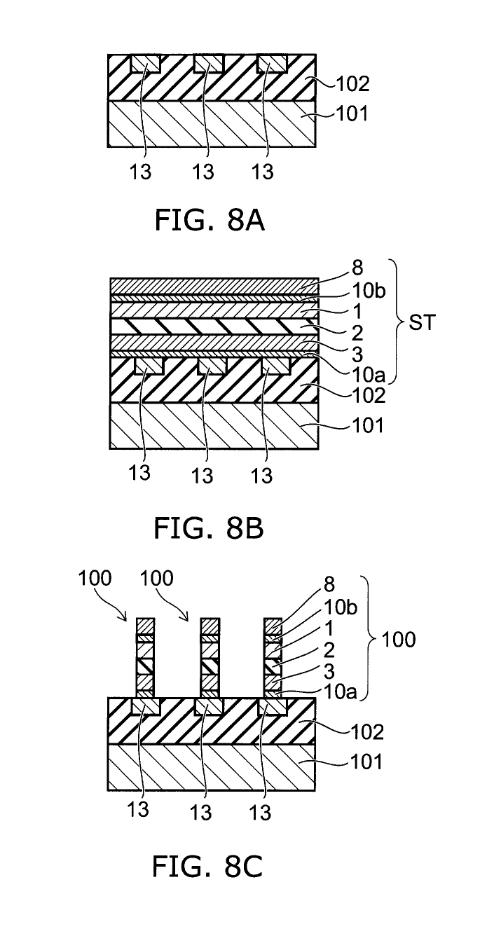

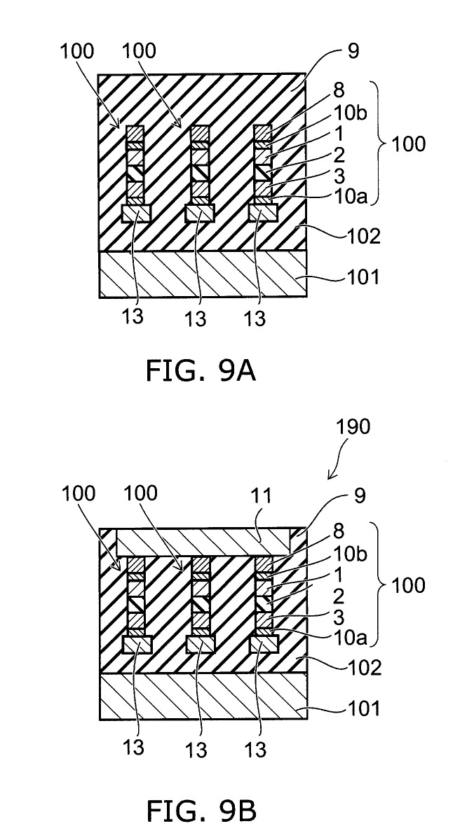

FIGS. 8A to 9B are schematic cross sectional views illustrating a manufacturing method of a nonvolatile memory device according to reference examples.

First of all, as shown in FIG. 8A, a MOS-FET or a contact which is not illustrated is formed on the silicone substrate 101, and the interlayer insulating film 102 is formed on the MOS-FET or contact. Next, the word line 13 is formed in accordance with an RIE or a damascene on the interlayer insulating film 102 using the metal such as W or the like.

Next, as shown in FIG. 8B, a laminated film ST of the barrier metal 10a, the counter electrode 3, the ion diffusion layer 2, the ion source electrode 1, the barrier metal 10b and the contact metal 8 is formed on the word line 13. Next, as shown in FIG. 8C, the laminated film ST is processed by the RIE or the like, and is separated per memory cell (function layer 100).

Next, as shown in FIG. 9A, after the interlayer insulating film 9 is embedded between the function layers 100, and is flattened by a chemical mechanical polishing (CMP) technique, the bit line 11 is formed as shown in FIG. 9B.

In the case of forming the function layer 100 in multiple stages, the word line 13, the function layer 100 and the bit line 11 may be formed on the bit line 11 in the same process as above, or the function layer 100 may be formed on the bit line 11 by making the bit line 11 shared, and the word line 13 may be formed on the function layer 100. An example to which the function layer 100 is applied may be any one of those shown in FIGS. 7A to 7F. By repeatedly laminating the word line 13, the bit line 11 and the function layer 100, a nonvolatile memory device 190 having a laminated type cross point memory cell array is completed.

In the nonvolatile memory device 190 according to the reference examples mentioned above, a large capacity of the element is realized by reducing a cell area, that is, refining the cell and setting the memory array in multiple stages. The multiple stage formation of the memory array has a limit in that a bit cost is increased due to an increase of the number of processes. The large capacity of the element greatly contributes to the reduction of the cell area caused by the refining of the memory cell even in the laminated type cross point memory cell array.

If the refining of the cell area is advanced, it is necessary to reduce a dimension in a vertical direction of the cell. This is because an aspect ratio of the cell becomes large if only the refining of the cell area is advanced, whereby a collapse of a pattern tends to occur in a cell processing process or a washing process after the process.

However, in the cell configuration mentioned above, the film thickness of the ion diffusion layer 2 has a correlation with the electric voltage in a leak current and a set of the memory cell, and it is not possible to simply make the film thinner according to the refining of the cell area. Therefore, in order to maintain the aspect ratio caused by the refining of the cell, it is required to make the counter electrode 3 and the ion source electrode 1 thinner.

Further, in many cases, a noble metal element is preferable for the material of the ion source electrode 1 for achieving an excellent switch property, and in the light of a cost reduction and a reduction of difficulty in the cell process by the RIE, it is required to make the film as thinner as possible.

However, if the ion source electrode 1 is formed as the thin film, the metal serving as the ion source tends to be agglutinated. Ag and Cu are suitable for the metal of the ion source in the ion diffusion type CBRAM. These metal materials are unstable in an energy state in the thin film, are hard to become a uniform film, and tend to be agglutinated. For example, Ag does not become the uniform film in the film thickness not more than 20 nm or not more than 30 nm, and particularly it becomes a particle shape having a diameter of between about 20 nm and 30 nm, regardless of a film forming condition, if it is exposed to the ambient air.

If the metal to become the ion source is agglutinated as mentioned above, a grain diameter distribution can not be disregarded with respect to the refining of the cell area. Particularly, in a generation in which the size of the cell is not more than 10 nm, the cell size becomes smaller than the grain diameter of the agglutinated ion source, and a dispersion of an electric property of the cell caused by the manufacturing process and a generation of the defect bit are not avoidable.

In the nonvolatile memory device 110 according to the embodiment, since the close contact layers 141 and 143 which are described previously are provided, the agglutination of the ion source 1 formed on the close contact layers 141 and 143 is suppressed, and a uniform ion source layer is formed. As a result, it is possible to suppress the dispersion of the electric property of the memory cell and the generation of the defect bit.

### Second Embodiment

Next, a description will be given of a manufacturing method of the nonvolatile memory device.

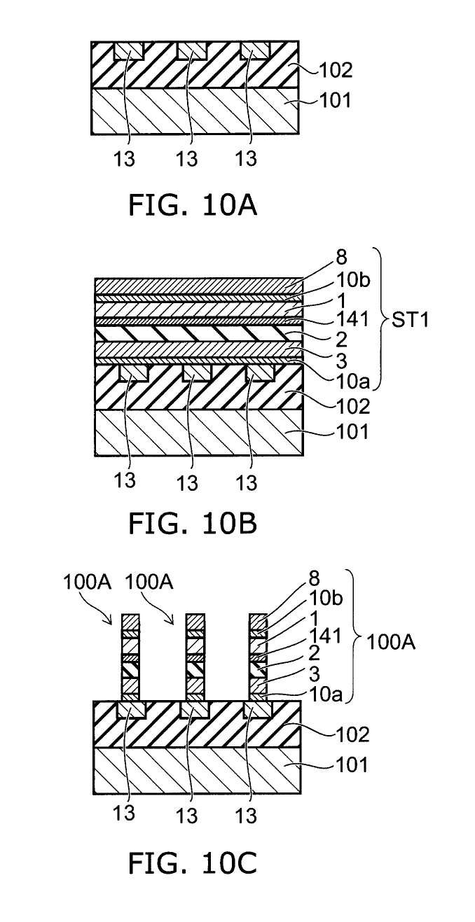

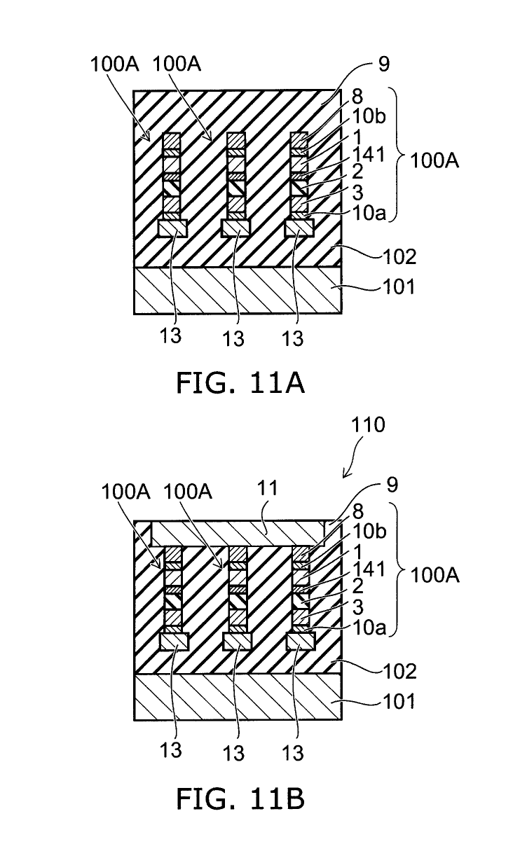

FIGS. 10A to 11B are schematic cross sectional views illustrating a manufacturing method of a nonvolatile memory device according to the embodiment.

FIGS. 10A to 11B show the manufacturing method of the nonvolatile memory device 110 having the first function layer 100A.

First of all, as shown in FIG. 10A, the MOS-FET or the contact which is not illustrated is formed on the silicone substrate 101, and the interlayer insulating film 102 is formed the MOS-FET or contact. Next, the word line 13 is formed in accordance with the RIE or the damascene on the interlayer insulating film 102 using the metal such as W or the like.

Next, as shown in FIG. 10B, a laminated film ST1 of the barrier metal 10a, the counter electrode 3, the ion diffusion layer 2, the close contact layer 141, the ion source electrode 1, the barrier metal 10b and the contact metal 8 is formed on the word line 13.

Since the close contact layer 141 is formed on the ion diffusion layer 2, and the ion source electrode 1 is formed on the close contact layer 141, at a time of forming the laminated film ST1, the agglutination of the ion source electrode 1 is suppressed, and a uniform ion source layer is formed.

Next, as shown in FIG. 10C, the laminated film ST1 is processed by the RIE or the like, and is separated per memory cell (first function layer 100A).

Next, as shown in FIG. 11A, after the interlayer insulating film 9 is embedded between the function layers 100, and is flattened by a CMP technique, the bit line 11 is formed as shown in FIG. 11B. As a result, the nonvolatile memory device 110 having one stage of first function layer 100A is completed.

In the case of manufacturing the nonvolatile memory device 110 having another first function layer 100AA, the close contact layer 142 may be formed on the ion source electrode 1 and the barrier metal 10b may be formed on the close contact layer 142, in the formation of the laminated film ST1.

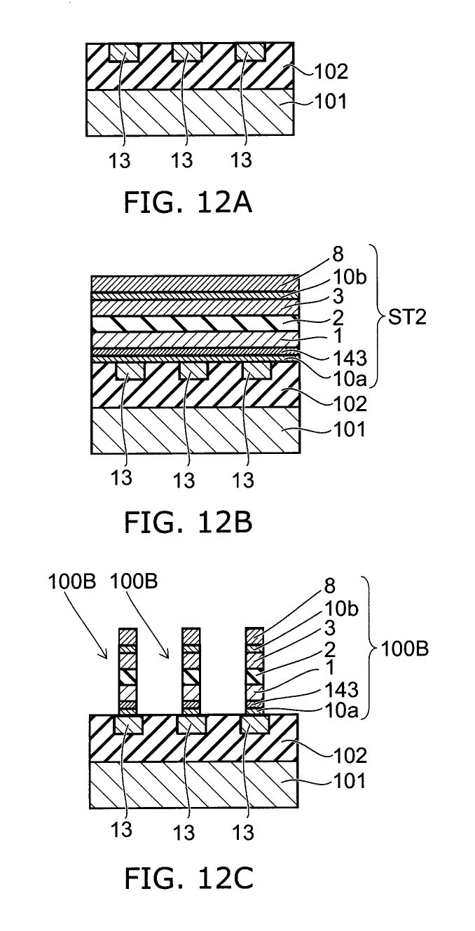

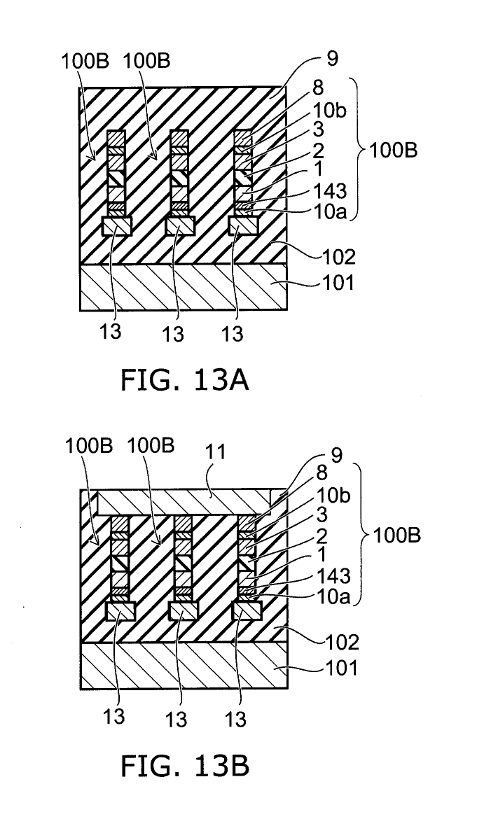

FIGS. 12A to 13B are schematic cross sectional views illustrating a manufacturing method of a nonvolatile memory device in accordance with another configuration.

FIGS. 12A to 13B show the manufacturing method of the nonvolatile memory device 110 having the second function layer 100B.

First of all, as shown in FIG. 12A, the MOS-FET or the contact which is not illustrated is formed on the silicone substrate 101, and the interlayer insulating film 102 is formed on the MOS-FET or contact. Next, the word line 13 is formed in accordance with the RIE or the damascene on the interlayer insulating film 102 using the metal such as W or the like.

Next, as shown in FIG. 12B, a laminated film ST2 of the barrier metal 10a, the close contact layer 143, the ion source electrode 1, the ion diffusion layer 2, the counter electrode 3, the barrier metal 10b and the contact metal 8 is formed on the word line 13.

Since the close contact layer 143 is formed on the barrier metal 10a, and the ion source electrode 1 is formed on the close contact layer 143, at a time of forming the laminated film ST2, the agglutination of the ion source electrode 1 is suppressed, and a uniform ion source layer is formed.

Next, as shown in FIG. 12C, the laminated film ST2 is processed by the RIE or the like, and is separated per memory cell (second function layer 100B).

Next, as shown in FIG. 13A, after the interlayer insulating film 9 is embedded between the function layers 100, and is flattened by the CMP technique, the bit line 11 is formed as shown in FIG. 13B. As a result, the nonvolatile memory device 110 having one stage of second function layer 100B is completed.

In the case of manufacturing the nonvolatile memory device 110 having another second function layer 100BB, the close contact layer 144 may be formed on the ion source electrode 1 and the ion diffusion layer 2 may be formed on the close contact layer 142, in the formation of the laminated film ST2.

In any of the manufacturing method shown in FIGS. 10A to 11B, and the manufacturing method shown in FIGS. 12A to 13B, the nonvolatile memory device 110 having the multiple stages of function layers 100 is completed by repeating the process of forming any one of the laminated films ST1 and ST2 on the bit line 11, processing by the RIE or the like so as to separate per memory cell, and embedding by the interlayer insulating film 9.

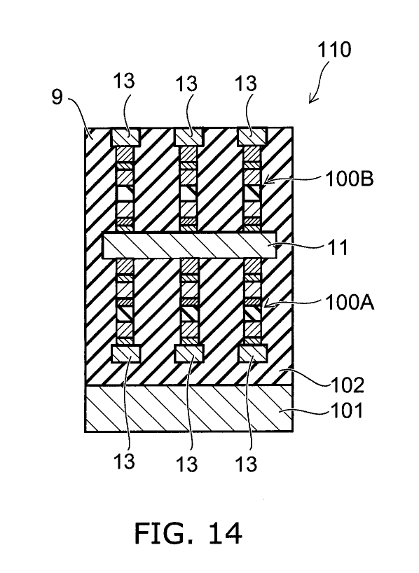

FIG. 14 is a schematic cross sectional view of a nonvolatile memory device having two stages of function layers.

In the example shown in FIG. 14, for example, the bit line 11 provided between the upper and lower function layers 100 is used as either the upper or lower function layer 100.

In the example shown in FIG. 14, the first function layer 100A is provided between the word line 13 and the bit line 11 the world line 13, and the second function layer 100B is provided between the bit line 11 and the word line 13 on the bit line 11.

As a combination of the upper and lower function layers 100 (the first function layer 100A and the second function layer 100B), any one of FIGS. 7C to 7F or a plurality of combinations of FIGS. 7C to 7F can be applied.

As described above, in accordance with the nonvolatile memory device and the manufacturing method the nonvolatile memory device according to the embodiments, it is possible to achieve the equalization of the film thickness of the first electrode layer, and the improvement of the close contact property between the first electrode layer and the variable resistance layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory device comprising:
a first function layer including a first electrode layer, a second electrode layer opposed to the first electrode layer, and a variable resistance layer provided between the first electrode layer and the second electrode layer, resistance state of the variable resistance layer being variable,
the first function layer including a first intermediate layer which is provided between the first electrode layer and the variable resistance layer, the first function layer contacting each of the first electrode layer and the variable resistance layer.

2. The device according to claim 1, wherein
a work function of a metal element included in the first electrode layer is larger than a work function of a metal element included in the first intermediate layer.

3. The device according to claim 1, wherein
a metal included in the first electrode layer is at least one selected from the group consisting of Cu, Ag, Al, Co and Ni.

4. The device according to claim 1, wherein
a metal included in the first intermediate layer is at least one selected from the group consisting of Ti, Nb, Hf, Al and Ta.

5. The device according to claim 1, wherein
the first function layer includes a second intermediate layer contacting a surface in an opposite side to the first intermediate layer of the first electrode layer.

6. The device according to claim 5, wherein
a work function of a metal element included in the first electrode layer is larger than a work function of a metal element included in the second intermediate layer.

7. The device according to claim 5, wherein
a metal included in the second intermediate layer is at least one selected from the group consisting of Ti, Nb, Hf, Al and Ta.

8. A nonvolatile memory device comprising:
a second function layer including a first electrode layer, a second electrode layer opposed to the first electrode layer, and a variable resistance layer provided between the first electrode layer and the second electrode layer, resistance state of the variable resistance layer being variable,
the second function layer including a third intermediate layer contacting a surface in an opposite side to the variable resistance layer of the first electrode layer.

9. The device according to claim 8, wherein
a work function of a metal element included in the first electrode layer is larger than a work function of a metal element included in the third intermediate layer.

10. The device according to claim 8, wherein
a metal included in the first electrode layer is at least one selected from the group consisting of Cu, Ag, Al, Co and Ni.

11. The device according to claim 8, wherein
a metal included in the third intermediate layer is at least one selected from the group consisting of Ti, Nb, Hf, Al and Ta.

12. The device according to claim 8, wherein
the second function layer includes a fourth intermediate layer which is provided between the first electrode layer and the variable resistance layer, the fourth intermediate layer contacting each of the first electrode layer and the variable resistance layer.

13. The device according to claim 12, wherein
a work function of a metal element included in the first electrode layer is larger than a work function of a metal element included in the fourth intermediate layer.

14. The device according to claim 12, wherein
a metal included in the fourth intermediate layer is at least one selected from the group consisting of Ti, Nb, Hf, Al and Ta.

15. A method for manufacturing a nonvolatile memory device, comprising:
forming a first function layer, the first function layer including a first electrode layer, a second electrode layer opposed to the first electrode layer, and a variable resistance layer provided between the first electrode layer and the second electrode layer, resistance state of the variable resistance layer being variable,
the forming the first function layer including:
forming the second electrode layer;
forming the variable resistance layer on the second electrode layer;
forming a first intermediate layer on the variable resistance layer, the first intermediate layer contacting the variable resistance layer; and
forming the first electrode layer on the first intermediate layer, the first electrode layer contacting the first intermediate layer.
